(19) United States
(12) Patent Application Publication
(10) Pub. No.: US 2008/0296779 A1
(43) Pub. Date: Dec. 4, 2008

(54) SEMICONDUCTOR DEVICE AND METHOD OF MANUFACTURING THE SAME

(75) Inventors: Satoshi MATSUI, Kawasaki (JP); Yoichiro Kurita, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, Kawasaki (KR)

(21) Appl. No.: 12/127,149

(22) Filed: May 27, 2008

(30) Foreign Application Priority Data
May 28, 2007 (JP) 2007-140751

(51) Int. Cl. H01L 23/538; H01L 21/58

(52) U.S. Cl. 257/777; 438/109; 257/E23.169; 257/E21.505

(57) ABSTRACT

Aimed at providing a semiconductor device improved in reliability of bonding and yield of products, even when semiconductor chips having through electrodes are used, the semiconductor device of the present invention has a substrate; a stack placed on the substrate, and composed of a plurality of semiconductor chips (first semiconductor chip and second semiconductor chip), each having through electrodes, stacked while placing bumps connected to the through electrodes in between; and a reinforcing chip (semiconductor chip) provided on the stack specifically on the surface thereof opposite to the substrate-side surface, or between the substrate and the stack, wherein thickness of the reinforcing chip is larger than the thickest semiconductor chip out of the plurality of semiconductor chips.

This application is based on Japanese patent application No. 2007-140751 the content of which is incorporated hereinto by reference.

### BACKGROUND

1. Technical Field

The present invention relates to a semiconductor device having a plurality of semiconductor chips, each having through electrodes, stacked on a substrate, and a method of fabricating the same.

2. Related Art

An example of conventional semiconductor device can be found in 2002 Electronic Components and Technology Conference (ECTC2002), p. 473-479, “Mechanical Effects of Copper Through-Vias in a 3D Die-Stacked Module”. The semiconductor device described in this literature is shown in FIG. 6B.

As shown in FIG. 6B, the semiconductor device has a substrate 112, a plurality of semiconductor chips 120 stacked on the substrate 112, and an encapsulating material 134. The substrate 112 has a single-layered or multi-layered interconnect layer not shown, and is composed of silicon or an organic material. The substrate 112 has a plurality of solder balls 114 arranged on the back surface thereof. The plurality of semiconductor chips 120 are electrically connected by bumps 124 which are connected to the individual through electrodes 122.

Japanese Laid-Open Patent Publication No. 2004-87732 describes a semiconductor device having, on a first semiconductor chip, a second semiconductor chip thicker than the first semiconductor chip bonded thereto by flip-chip bonding.

The patent publication describes that, by making the first semiconductor chip having a larger line width thinner than the second semiconductor chip, the semiconductor device successfully concentrates effects of distortion, possibly occurs in the process of mounting, to the thinner first semiconductor chip, thereby reduces the amount of distortion of the thicker second semiconductor chip, and consequently reduces influences of the distortion on circuit interconnects after the mounting. No description, however, on the through electrodes can be found in Japanese Laid-Open Patent Publication No. 2004-87732.

The semiconductor chip having the through electrodes is as thin as 50 to 100 μm or around, for the reason related to process of forming the through electrodes, and is therefore low in strength and is likely to warp. For this reason, the conventional techniques described in the literatures in the above have still some room for improvement in the aspects below.

First, the semiconductor device described in ECTC2002 has occasionally resulted in fracture of the bumps 124 connecting the semiconductor chips 120, in the process of manufacturing or practical use. In such semiconductor device, reliability of bonding between the semiconductor chips having the through electrodes and the substrate may degrade, and thereby yield of products may degrade.

Second, the semiconductor chip is only as very thin as 50 to 100 μm, so that further thinning of another semiconductor chip, in the attempt of applying the technique described in the patent publication to the semiconductor chips having through electrodes, may result in further decrease in strength and increase in warping. Moreover, the distortion cannot be reduced only by providing such a small difference in thickness of the semiconductor chips having a thickness of only as small as 50 to 100 μm or around. Conversely, there may be an idea of thicken another semiconductor chip. Thickening of the semiconductor chip having the through electrodes may, however, raise practical problems in that etching process for forming the through electrodes may take a longer time.

As will be understood from the above, the technique described in Japanese Laid-Open Patent Publication No. 2004-87732 is not applicable to the semiconductor device using the semiconductor chips having the through electrodes.

### SUMMARY

The present inventors went into thorough investigations into the first problem described in the above, and obtained the findings below. The findings will be explained referring to sectional views by processes shown in FIGS. 5A and 5B, and FIGS. 6A and 6B.

In FIG. 5A, the substrate 112 is preliminarily heated at around 100° C. The substrate 112 is placed on a stage (not shown). A thin semiconductor chip 120 having the through electrodes 122 is heated to 200 to 450° C. or around, which is fusing temperature of solder, and mounted on the heated substrate 112. The substrate is kept under high temperatures over a longer period than the semiconductor chip is kept. Therefore, if the substrate should be heated to higher temperatures of 200 to 450° C. or around, surfaces of interconnect materials or solder formed on the substrate may be oxidized, followed by degradation in quality and yield of products. For this reason, the substrate is heated only to as high as 100° C., which is lower than heating temperature of the semiconductor chip.

Then as shown in FIG. 5B, the semiconductor chip 120 heated to 200 to 450° C. or around is further mounted.

By repeating the process steps as described in the above, the semiconductor chips 120 are stacked, and then cooled to normal temperature or around to fix the solder bonding (FIG. 6A). The solder balls 114 are then formed on the back surface of the substrate 112. The product is then packaged by an encapsulating material 134, to thereby manufacture the semiconductor device (FIG. 6B).

However, in this method of manufacturing, the semiconductor chip 120 needs a larger range of lowering in temperature before normal temperature is recovered than the substrate 112 needs, because of initial difference in temperature between the semiconductor chip 120 to be mounted and the substrate 112. For this reason, even if the substrate 112 should be composed of the same material, or silicon, with the semiconductor chip 120, the semiconductor chip 120 causes a larger amount of thermal shrinkage than the substrate 112 causes, and stress ascribable to the difference in the amount of thermal shrinkage may be concentrated at the boundary between the substrate 112 and the semiconductor chip 120.

Such concentration of stress may result in fracture of the bumps 124 bonding the substrate 112 and the semiconductor chip 120, as shown in FIG. 7, and may cause warping of the entire module. Based on these novel findings, the present inventors completed the present invention.

More specifically, according to the present invention, there is provided a semiconductor device which includes a substrate; a stack placed on the substrate, and composed of a plurality of semiconductor chips, each having through electrodes, stacked while placing bumps connected to the through electrodes in between; and a reinforcing chip provided on the stack specifically on the surface thereof opposite to the substrate-side surface, or between the substrate and the stack, wherein thickness of the reinforcing chip is larger than the thickest semiconductor chip out of the plurality of semiconductor chips.

The semiconductor device of the present invention has a reinforcing chip thicker than the thickest semiconductor chip out of the plurality of semiconductor chips, on the stack specifically on the surface thereof opposite to the substrate-side surface, or between the substrate and the stack.

By virtue of this configuration, rigidity of the stack may be improved even if thin chips, such as the semiconductor chips having the through electrodes, are stacked. Accordingly, fracture of the bumps due to concentration of stress may be suppressed, and warping of the stack may be reduced. As a consequence, the semiconductor device may be improved in reliability of bonding and yield of products.

A semiconductor chip or a dummy chip may be adoptable to the reinforcing chip in the present invention. The dummy chip may be a substrate having no passive elements nor positive elements mounted thereon, and is therefore not contributive to any electrical functions of the semiconductor device, or may be a semiconductor substrate having only passive elements provided thereto.

According to the present invention, there is provided a semiconductor device improved in reliability of bonding and yield of products, even when the semiconductor chips having the through electrodes are used, and a method of manufacturing the semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view schematically showing a semiconductor device according to a first embodiment;

FIGS. 2A and 2B are sectional views showing process steps of a method of manufacturing a semiconductor device according to a second embodiment;

FIG. 3 is a sectional view schematically showing a semiconductor device according to the second embodiment;

FIG. 4 is a sectional view schematically showing a semiconductor device according to another embodiment;

FIGS. 5A to 6B are sectional views showing process steps of a conventional method of manufacturing a semiconductor device;

FIG. 7 is a partially enlarged sectional view explaining a problem in the conventional method of manufacturing a semiconductor device;

FIG. 8 is a drawing explaining a method of three-point bending test in the embodiments of the present invention; and

FIG. 9 is a graph showing analytical results relevant to relations between thickness of the semiconductor chip 30 and amount of warping of the first semiconductor chip 20a in Example 2.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiment illustrated for explanatory purposes.

Embodiments of the present invention will be described below referring to the attached drawings. In all drawings, any similar constituents will be given with similar reference numerals, and the explanation will not always be repeated.

### First Embodiment

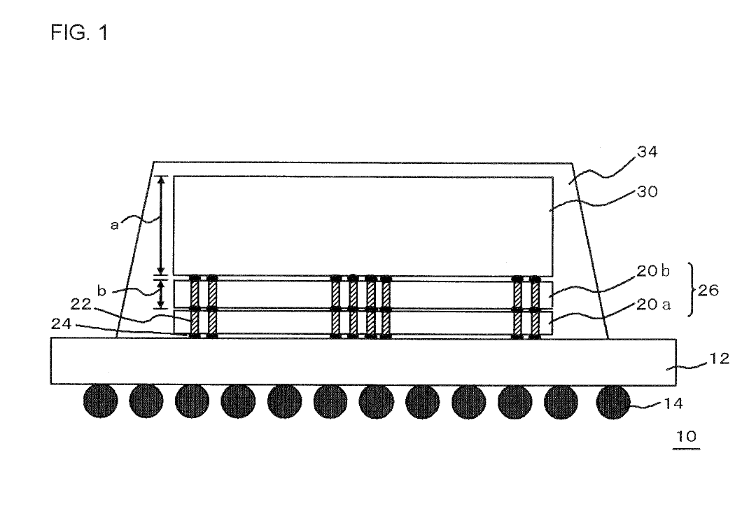

As shown in FIG. 1, a semiconductor device 10 of this embodiment has a substrate 12, a stack 26 composed of a first semiconductor chip 20a and a second semiconductor chip 20b stacked on the substrate 12, and a reinforcing chip (semiconductor chip 30) provided to the top surface of the stack 26.

The substrate 12 has a plurality of solder balls 14 on the back surface thereof. A package substrate composed of silicon or an organic material may be used as the substrate 12. The substrate 12 is approximately 200 μm in thickness.

The first semiconductor chip 20a has a plurality of through electrodes 22. The first semiconductor chip 20a is electrically connected via bumps 24 with the substrate 12 and the second semiconductor chip 20b, using vertical interconnects. The bumps used for connecting the semiconductor chips, having the through electrodes, are smaller than those used for flip-chip bonding of general semiconductor chip having no through electrode, and will therefore be referred to as “microbumps” hereinafter. The microbumps in the context of this patent specification mean those having a diameter of 50 μm or smaller. The microbumps 24 used in this embodiment has a diameter of 20 to 30 μm.

The second semiconductor chip 20b may have functional elements similar to, or different from those on the first semiconductor chip 20a. The second semiconductor chip 20b has a plurality of through electrodes 22. The second semiconductor chip 20b is electrically connected via microbumps 24 with the first semiconductor chip 20a and the semiconductor chip 30 (reinforcing chip), using vertical interconnects.

Thickness b of the second semiconductor chip 20b is approximately 50 μm. Thickness of the first semiconductor chip 20a and the second semiconductor chip 20b is nearly equal.

A general semiconductor chip may be adoptable as the semiconductor chip 30 (reinforcing chip). The semiconductor chip 30 has no through electrodes, and has a plurality of microbumps 24 on one surface thereof. The semiconductor chip 30 is electrically connected with the second semiconductor chip 20b via the microbumps 24.

The semiconductor chip 30 is thicker than the first semiconductor chip 20a or the second semiconductor chip 20b. Thickness “a” of the semiconductor chip is twice or more as large as thickness “b” of the second semiconductor chip 20b, and preferably three times or more. The thickness “a” of the semiconductor chip 30 may be adjusted to 120 μm to 400 μm or around.

Relation between the thickness of chip and bending stress will now be explained. As is well known in the field of material dynamics, relation between bending stress F of a cantilever and amount of warping h is given by the formula 1.

h=(2FL³)/(t³WE) Formula 1:
(t: thickness of a single chip, W: width of chip, F: bending stress, L: length of chip, E: Young's modulus of Si)

Formula 1 teaches that the amount of warping h is inversely proportional to cubic of thickness t of the chip. Large thickness t results in large improvement in the chip strength. More specifically, rigidity of a stack composed of n layers of chips is proportional to the number of layers, given by only n-fold rigidity of a single chip. In contrast, rigidity of a chip having an n-fold thickness gives n³-fold rigidity, showing large improvement.

Also flexural strength of the semiconductor chip is again proportional to cubic of thickness of the chip. Therefore, preferable flexural strength of the semiconductor chip 30 may be expressed also by a ratio of flexural strength in relation to the first semiconductor chip 20a. In other words, the flexural strength of the semiconductor chip 30 may be increased to as much as 8 times or more, preferably 10 times or more, and still more preferably 27 or more of that of the first semiconductor chip 20a.

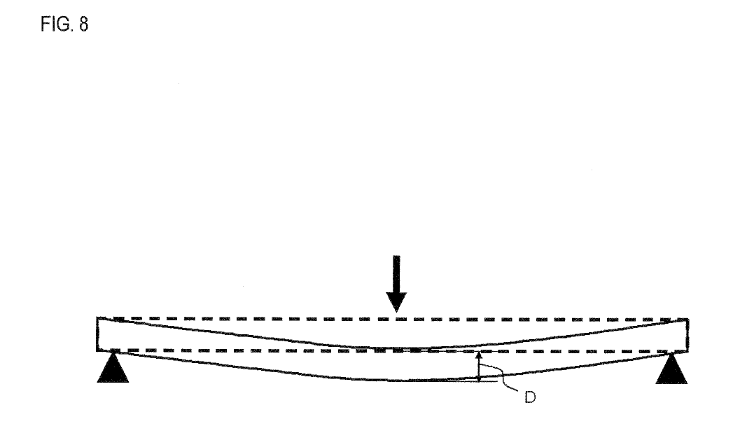

The flexural strength may be measured by three-point bending test. In the three-point bending test, the chip is supported at both ends as shown in FIG. 8, and amount of deformation D observed when a load is applied at the center is measured. A quantitative index of the flexural strength may be given by 1/D. This method is most widely used as a method of measuring strength of thin chips, and is measurable using a commercially-available instrument.

The individual gaps formed between every adjacent ones of the substrate 12, the first semiconductor chip 20a, the second semiconductor chip 20b, and the semiconductor chip 30 are filled with an underfill material (not shown). These gaps are approximately 20 μm high.

The underfill material adoptable herein may be any of those having coefficient of thermal expansion larger than that of the first semiconductor chip 20a or the second semiconductor chip 20b, and may typically be an epoxy resin-containing underfill material.

The stack 26 is molded by an encapsulating material 34.

A method of manufacturing thus-configured semiconductor device of this embodiment will be explained below.

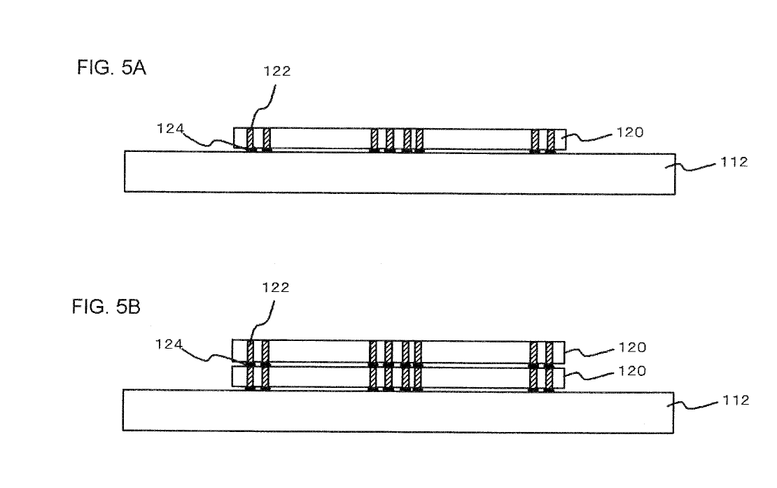

The processes up to mounting of the first semiconductor chip 20a and the second semiconductor chip 20b onto the substrate 12 are same as those shown in FIGS. 5A and 5B. Thereafter, similarly to bonding of the first semiconductor chip 20a and the second semiconductor chip 20b, the semiconductor chip 30 (reinforcing chip) heated to 200 to 450° C. is bonded on the second semiconductor chip 20b. The product is cooled to room temperature so as to complete solder bonding. The solder balls 14 are then mounted on the back surface of the substrate. The individual gaps formed between every adjacent ones of the substrate 12, the first semiconductor chip 20a, the second semiconductor chip 20b, and the semiconductor chip 30 are filled with an underfull material, and the product is packaged using the encapsulating material 34, to thereby manufacture the semiconductor device 10.

Effects of the first embodiment will be explained below.

In this embodiment, on the top surface of the stack 26 configured by stacking the first semiconductor chip 20a and the second semiconductor chip 20b, each having the through electrodes 22, the semiconductor chip 30 thicker than any of the semiconductor chip 20a and the second semiconductor chip 20b is provided.

By virtue of this configuration, rigidity of the stack 26 configured by stacking the thin first semiconductor chip 20a and the second semiconductor chip 20b, both having through electrodes, may be improved. Similarly to the conventional method, amount of thermal shrinkage of the semiconductor chips in the process of recovering normal temperature may be larger than that of the substrate also in the method of manufacturing according to this embodiment, due to initial difference in temperature of the semiconductor chips to be mounted and the substrate. However, provision of the semiconductor chip 30 as a reinforcing chip successfully improves the rigidity of the stack 26, thereby fracture of the microbumps 24 between the substrate 12 and the first semiconductor chip 20a due to stress concentration may be suppressed, and warping of the stack 26 may be reduced. As a consequence, the semiconductor device may be improved in reliability of bonding, and also in yield of products.

In addition, improvement in the rigidity of the package also improves resistance against thermally-induced internal stress or external stress, and suppression of fracture of the microbumps connecting the first semiconductor chip 20a and the second semiconductor chip 20b may improve reliability of bonding of the microbumps and yield of the semiconductor device.

In this embodiment, flexural strength of the semiconductor chip 30 may be increased to as much as 8 times of more, preferably 10 times or more, and still more preferably 27 times or more of that of the first semiconductor chip 20a or the second semiconductor chip 20b.

As a consequence, warping of the stack 26 due to stress concentration may further be reduced, and fracture of the microbumps 24 may effectively be suppressed, proving particular excellence in the above-described effects.

In this embodiment, the semiconductor chip 30 may be provided on the top surface of the stack 26.

In this configuration, the semiconductor chip 30 functions as a reinforcing component of the stack 26, and effectively improves rigidity of the stack 26. Therefore, fracture of the microbumps 24 induced by difference in the amount of thermal shrinkage in the process of solder bonding may effectively be suppressed.

Even if the microbumps 24 should cause fracture due to internal stress, and a part of, or entire portion of the stack 26 should warp in the process of solder bonding, a predetermined geometry may be recovered. More specifically, pressurizing from the top by contribution of the highly-rigid semiconductor chip 30 mounted on the top, and re-bonding through the microbumps 24 fused under heating may correct the bent stack 26 to recover a predetermined geometry. Therefore the semiconductor device may be improved in reliability of bonding, and yield of products.

In this embodiment, the microbumps may be used as the bumps.

When the first semiconductor chip 20a and the second semiconductor chip 20b, each having the through electrodes 22, are used, a large number of terminals for external connection may be exposed to both of the top and back surfaces of the first semiconductor chip 20a, so that the microbumps 24 are used for the purpose of connecting the chips. The microbumps 24 are, however, as small as 20 to 30 μm in diameter, ensuring only a small area of bonding. Small area of bonding may be more likely to cause fracture of the microbumps at the portion of bonding, and may degrade reliability of bonding, needing a higher level of completeness of the bonding.

According to the semiconductor device of this embodiment, warping of the stack 26 may be suppressed by the semiconductor chip 30 so as to ensure reliable bonding through the microbumps 24, so that the semiconductor device may be improved in reliability of bonding and yield of products, even when the microbumps are used.

In this embodiment, an underfill material containing an epoxy resin, having a coefficient of thermal expansion larger than that of the first semiconductor chip 20a and the second semiconductor chip 20b, may be used to fill the gap between the first semiconductor chip 20a and the second semiconductor chip 20b.

The underfill material shrinks during lowering from higher temperatures to normal temperature in the process of manufacturing or in practical use. The first semiconductor chip 20a and the second semiconductor chip 20b, configured as thin chips having the through electrodes 22, have occasionally resulted in local deformation of the underfill material at around the microbumps 24, and have resulted in crack of the chips, if the underfill material having a large coefficient of thermal expansion was placed in the gap therebetween.

In contrast, the semiconductor device configured according to this embodiment is improved in rigidity of the chip by virtue of the semiconductor chip 30, so that the local deformation of the chips ascribable to difference in the amount of shrinkage may be suppressed, thereby the stress is suppressed, and crack of the chips or the like may be suppressed.

The semiconductor device configured according to this embodiment need almost no modification of the package structure and processes of manufacturing. Making the semiconductor chip 30 on the topmost layer thicker than the first semiconductor chip 20a or the second semiconductor chip 20b is merely a sort of modification of the manufacturing conditions, because this may be accomplished simply by adjusting the thickness of a silicon wafer to a larger value in the process of back-side polishing, and is suppressive to increase in cost.

### Second Embodiment

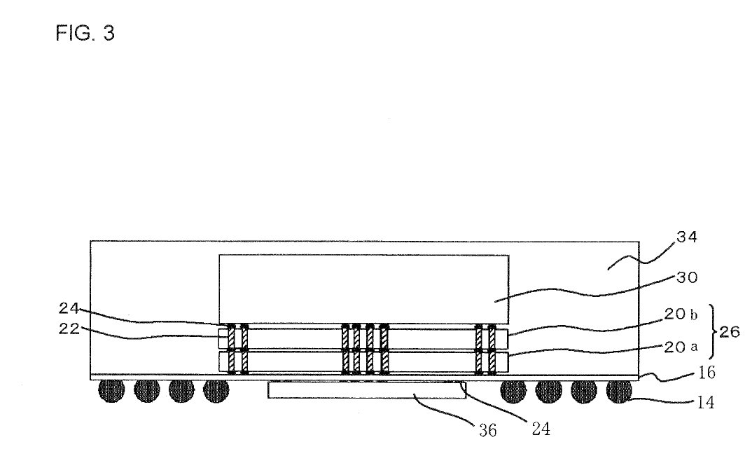

The semiconductor device of this embodiment has, as shown in FIG. 3, an interposer 16, the stack 26 configured by stacking, on the interposer 16, the first semiconductor chip 20a and the second semiconductor chip 20b, each having the through electrodes 22, and the semiconductor chip 30 (reinforcing chip) thicker than the first semiconductor chip 20a and the second semiconductor chip 20b, provided on the top surface of the stack 26. The first semiconductor chip 20a and the second semiconductor chip 20b are 50 μm thick, respectively.

A third semiconductor chip 36 is mounted on the back surface of the interposer 16, while placing the microbumps 24 in between.

As is understood from the above, the semiconductor device of this embodiment has a SMAFTI (SMArt chip connection with Feed-Through Interposer) package structure.

The interposer 16 is an extremely thin substrate (FTI: Feed-Through Interposer) containing an interconnect layer. The interposer 16 is composed of a stacked structure of an interconnect layer and an insulating resin layer composed of polyimide resin or the like. The interconnect layer is 7 μm thick, and the insulating resin layer is 8 μm thick. On the surface thereof on the interconnect layer side, the first semiconductor chip 20a is mounted while placing the microbumps in between. Further on the surface thereof on the insulating resin layer side, a plurality of electrodes for external connection (not shown) to which the solder balls 14 are connected are provided. The interposer 16 is as thick as 15 μm or around.

In this embodiment, memory chips may be adoptable to the first semiconductor chip 20a and the second semiconductor chip 20b, and a logic chip may be adoptable to the third semiconductor chip 36.

A method of manufacturing the semiconductor device of this embodiment will be explained below, referring to the attached drawings.

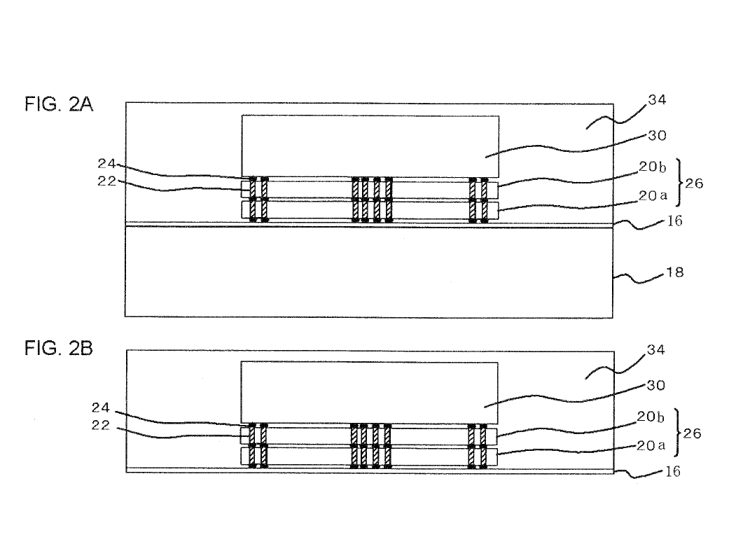

First, as shown in FIG. 2A, on the silicon wafer 18 provided with the interposer 16, the stack 26 is formed by stacking the first semiconductor chip 20a and the second semiconductor chip 20b, each having the through electrodes 22, similarly to as described in the first embodiment, and the semiconductor chip 30 (reinforcing chip) thicker than both of the first semiconductor chip 20a and the second semiconductor chip 20b is mounted on the stack 26. The underfill material is filled into the gaps formed between every adjacent ones of the interposer 16 and the individual chips, and the stack 26 is then molded by the encapsulating material 34.

The silicon wafer 18 is then removed from the back surface thereof so as to expose the insulating resin layer, to thereby form the interposer 16 (FIG. 2B). Next, the interposer 16, the stack 26, and the semiconductor chip 30 are heated up to 100° C. or around, and the third semiconductor chip 36, preheated at 200 to 450° C., is bonded to a predetermined position of the interposer 16 specifically on the surface thereof opposite to the surface having the stack 26 mounted thereon, while placing the microbumps 24 in between. The product is cooled to normal temperature, a plurality of solder balls 14 are formed, and then diced to produce the individual chips. The semiconductor device of this embodiment is obtained in this way (FIG. 3).

Effect of the second embodiment will be explained below.

Effects similar to those in the first embodiment may be obtained also in this embodiment, and reliability of bonding may further be improved even when the extremely thin interposer substrate (FTI substrate) only as thick as 15 μm or around is used.

Similarly to as in the first embodiment, also in the process of manufacturing of this embodiment, fracture of the bumps induced by stress concentration ascribable to difference in the amount of thermal shrinkage in the process of recovering normal temperature, originated from difference in temperature between the semiconductor chip 20a and the substrate composed of the silicon wafer 18 and the interposer 16, may be suppressed. In short, completely same effects with those in the first embodiment may be obtained.

This embodiment raises another effect. In the method of manufacturing a semiconductor device of this embodiment, as shown in FIGS. 2A and 2B, the silicon wafer 18 is removed so as to expose the insulating resin layer. Because the silicon wafer 18 supports the entire package, and at the same time functions as a reinforcing component, removal of the silicon wafer 18 may degrade rigidity of the package as a whole.

For this reason, any stress applied to the package in the process after the silicon wafer 18 was removed has occasionally deform the entire package, and has degraded flatness of the back surface of the interposer 16.

In the semiconductor device having the SMAFTI package structure, the third semiconductor chip 36 is mounted on the back surface of the interposer 16 while placing the microbumps 24 in between. Therefore, the microbumps 24 of the third semiconductor chip 36 have not occasionally been bonded at predetermined positions if the back surface of the interposer 16 was not flat, and yield of products have consequently degraded. In addition, because area of bonding through the microbumps 24 is small as described in the above, any incomplete bonding has occasionally resulted in fracture of the microbumps at the portions of bonding, to thereby degrade reliability of bonding.

The present inventors found out the problems described in the above, and completed the semiconductor device of this embodiment.

The semiconductor device of this embodiment has the extremely thin interposer 16 composed of an interconnect layer, the stack 26 configured by stacking, on the interposer 16, the first semiconductor chip 20a and the second semiconductor chip 20b, each having the through electrodes 22, while placing the microbumps 24 connected to the through electrodes 22 in between, and the semiconductor chip 30 thicker than the first semiconductor chip 20a and the second semiconductor chip 20b, provided on the top surface of the stack 26.

By virtue of this configuration, rigidity of the entire package may be improved, and thereby the back surface of the interposer 16 may be kept flat. Therefore, even when the third semiconductor chip 36 is mounted on the back surface of the interposer 16 in the semiconductor device having the SMAFTI package structure, degradation in yield of products ascribable to stress in the process of manufacturing, or degradation in reliability of bonding ascribable to stress in the practical use may be suppressed.

Embodiments of the present invention have been described referring to the attached drawings, merely as examples of the present invention, wherein various modified configurations other than those described in the above may be adoptable.

In the first and second embodiments, the semiconductor chip 30 may be provided between the substrate and the stack 26.

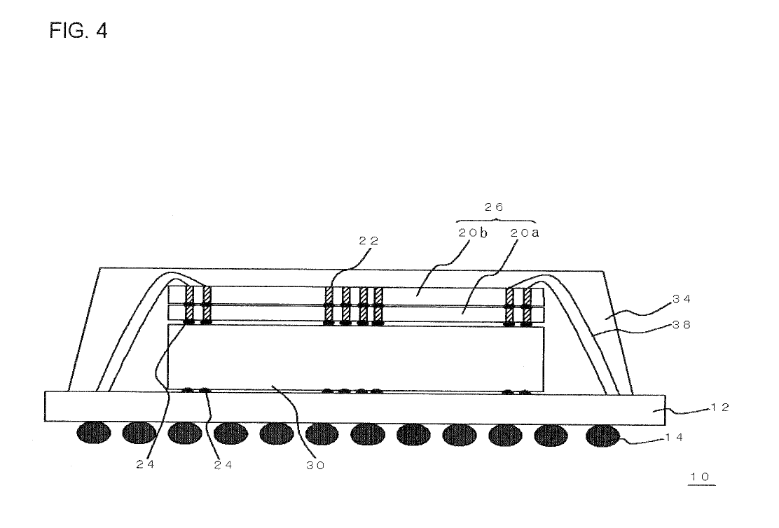

More specifically, as shown in FIG. 4, the semiconductor chip 30 may be mounted on the top surface of the substrate 12 while placing the microbumps 24 in between, and the first semiconductor chip 20a and the second semiconductor chip 20b are stacked in this order on the top surface of the semiconductor chip 30 to thereby form the stack 26. The second semiconductor chip 20b in the topmost layer is electrically connected to the substrate 12 through bonding wires 38. In this case, the semiconductor chip 30 may be replaced with a dummy chip, or any other semiconductor chip may be provided between the substrate 12 and the semiconductor chip 30, and between the semiconductor chip 30 and the stack 26.

In the first and second embodiments, still another semiconductor chip may be provided between the stack 26 and the semiconductor chip 30, and over the semiconductor chip 30.

The first and second embodiments showed exemplary cases of stacking the first semiconductor chip 20a and the second semiconductor chip 20bd, without special limitation, wherein three or more semiconductor chips having through electrodes may be stacked.

In the first and second embodiments, the semiconductor chip 30 may be replaced with a dummy chip having the microbumps 24. The dummy chip may have a passive element.

The dummy chip is preferably composed of a material having a coefficient of thermal expansion nearly equal to that of the first semiconductor chip 20a. More specifically, the coefficient of thermal expansion is preferably 0.5 to 5 ppm/° C. This sort of materials may be exemplified by silicon, glass, ceramic, and so forth. Fracture of the microbumps 24 may thus be suppressed.

As for a silicon-containing dummy chip, a silicon substrate having only the microbumps 24 formed thereon may readily be manufactured by general processes, so that increase in the cost of manufacturing, which may otherwise result from increase in the number of process steps, may be suppressed.

In the first and second embodiments, the total thickness of the stack 26 and the semiconductor chip 30 (height of module) may be equalized by varying the thickness of the semiconductor chip 30 for every package or every product.

In this way, an effect of largely reducing the number of process steps and cost in the final packaging process, for example, may be obtained. More specifically, in the process of encapsulating the module with the encapsulating material 34 to produce a final package form, and if the package is mold resin-encapsulated package, a die may be set therearound, and a mold resin may be injected thereinto. If the height of module should vary from product to product, dies having a variety of height as being adapted to the individual products may be necessary. Exchange of the dies may undesirably take a long time.

In contrast, preliminary adjustment of the height in the stage of stacking allows preparation of only a single die, and this may contribute to reduction in cost and time of manufacturing. Alternatively, as for the package of a type attached with a heat spreader (Cu plate), it may otherwise be necessary to prepare various heights of heat spreaders as being adapted to height of the modules, whereas equalized height of modules may allow the process steps to be shared by all products, and may reduce the number of process steps and cost for manufacturing.

In the first and second embodiments, the thickness of the semiconductor chip 30 may be varied for every package or every product, and may be adjusted to an integer multiplication of the thickness of the stacked first semiconductor chip 20a. “The thickness of the stacked first semiconductor chip 20a” herein typically means the height measured from the surface of the substrate 12 up to the top surface of the first semiconductor chip 20a stacked on the surface of the substrate 12.

This configuration may facilitate equalization of the height of modules for every package or every product, and may effectively reduce the cost and time of manufacturing.

In addition, because the thickness of the encapsulating material over the surface of the semiconductor chip 30 may now be made uniform and thin, variation in the thickness of the encapsulating material 34 may be suppressed. As a consequence, the warping ascribable to difference in coefficient of thermal expansion between the encapsulating material 34 and the semiconductor chip 30 may be suppressed, and reliability of the package may be improved.

In the first and second embodiments, the thickness of the first semiconductor chip 20a and the second semiconductor chip 20b may be different from each other, provided that they are smaller than that of the semiconductor chip 30.

The semiconductor device of the second embodiment may be configured without using the third semiconductor chip 36.

### EXAMPLE 1

In semiconductor device A and semiconductor device B configured as described below, amount of warping of the semiconductor chips after the process step of stacking them was confirmed under the conditions below. Results are shown in Table 1.

(a) Semiconductor Device A
The semiconductor device 10 configured as shown in FIG. 1 was used.
Thickness: first semiconductor chip 20a=50 μm, second semiconductor chip 20b=50 μm, semiconductor chip 30=400 μm
Height (height of module) measured from the top surface of the substrate 12 to the top surface of the semiconductor chip 30: 540 μm
Temperature conditions in the process of stacking: substrate 12=100° C., first semiconductor chip 20a=second semiconductor chip 20b=semiconductor chip 30=300° C.
Cooling temperature: 25° C.

### (b) Semiconductor Device B

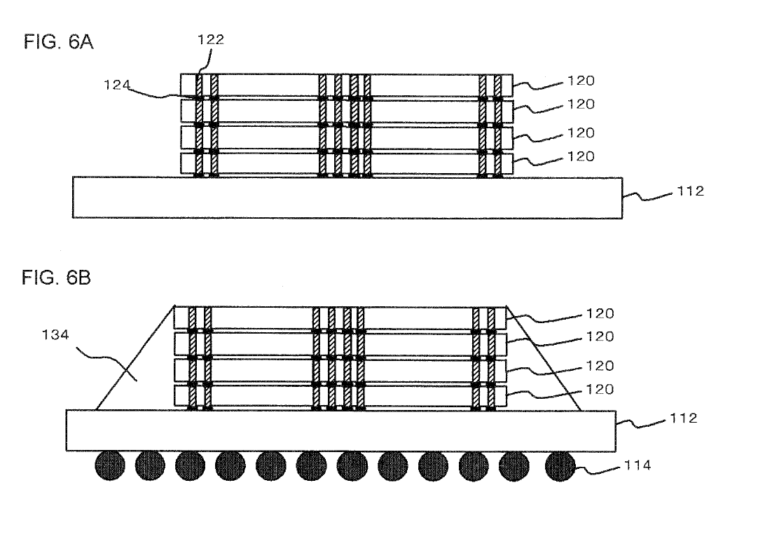

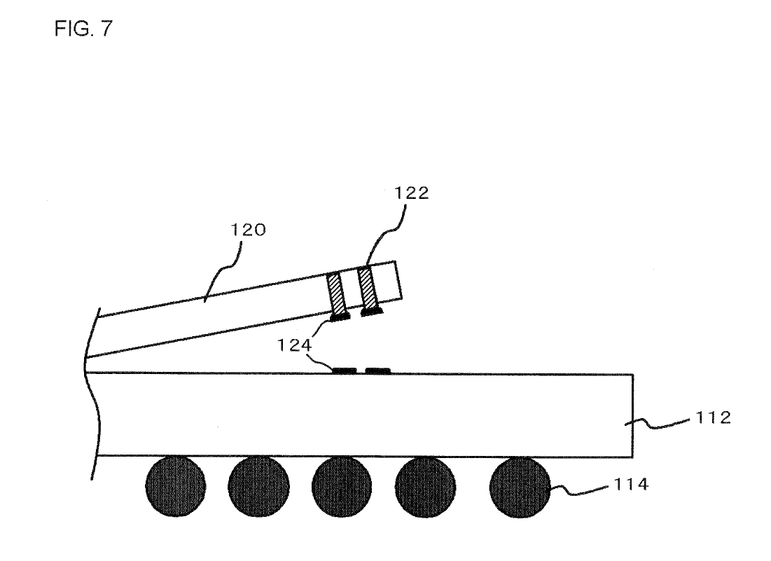

A semiconductor device configured as shown in FIG. 6B, except that eight semiconductor chips 120 were stacked, was used. Thickness: semiconductor chip 120=50 μm
Height (height of module) measured from the top surface of the substrate 112 to the top surface of the semiconductor chip 120: 540 μm
Temperature conditions in the process of stacking: substrate 112=100° C., semiconductor chip 120=300° C.
Cooling temperature: 25° C.

TABLE 1

| | Maximum | Rate of |
|---|---|---|
| | warping | increase in |
| | [μm] | warping (*) |
| Semiconductor | 15.5 | — |
| Device A | | |
| Semiconductor | 31.4 | +103% |
| Device B | | |

(*) Expressed by a rate of increase in comparison with the maximum warping of the semiconductor device A.

In comparison of the semiconductor device A with the semiconductor device B having the same height of module, the amount of warping of the semiconductor device B configured without using the semiconductor chip 30 (reinforcing chip) was found to increase by as much as 103% of the amount of warping of the semiconductor device A provided with the reinforcing chip.

From these results, it was confirmed that, by providing the reinforcing chip, even the semiconductor device having a plurality of semiconductor chips, each having the through electrodes 22, stacked therein may be improved in reliability of bonding and yield of products,.

### EXAMPLE 2

The semiconductor device configured as shown in FIG. 1 was subjected to numerical analysis (simulation) with respect to relation between the thickness of the semiconductor chip 30 and the amount of warping of the first semiconductor chip 20a. Conditions of calculation are shown below.
Thickness: first semiconductor chip 20a=50 μm, second semiconductor chip 20b=50 μm
Intervals between chips: 20 μm
Temperature conditions in the process of stacking: substrate 12=100° C., first semiconductor chip 20a=second semiconductor chip 20b=semiconductor chip 30=350° C.
Cooling temperature: 25° C.
Coefficient of thermal expansion and Young's modulus of the individual semiconductor chips: values for silicon were adopted.

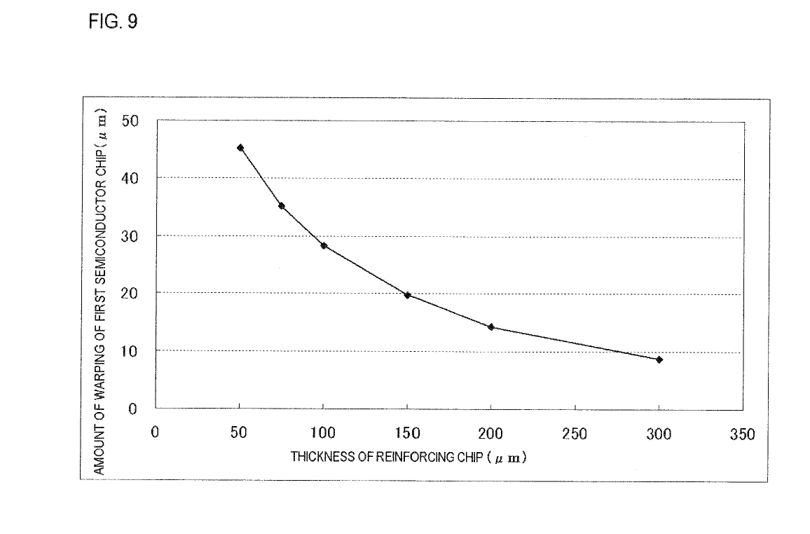

Results of the numerical analysis are shown in FIG. 9. In FIG. 9, the abscissa represents the thickness of the semiconductor chip 30 (reinforcing chip), and the ordinate represents the amount of warping (amount of deformation) of the first semiconductor chip 20a. The amount of warping of the first semiconductor chip 20a herein means the amount of deformation of the chip, correspondent to D shown in FIG. 8. In this analysis, in order to clearly estimate difference in the amount of warping ascribable to difference in thermal shrinkage, and an effect of the reinforcing chip, it was assumed that there were no microbumps connecting the first semiconductor chip 20a and the substrate 12.

From the results of analysis, it was found that the first semiconductor chip showed an amount of warping of approximately 46 μm, when the thickness of the semiconductor chip 30 (reinforcing chip) was 50 μm equally to that of the first or second semiconductor chip, and that the amount of warping was reduced by approximately 40% to give approximately 27 μm, when the thickness of the semiconductor chip 30 (reinforcing chip) was increased to 100 μm as being doubled from the thickness of the first or second semiconductor chip. It was also found that, by further increasing the thickness of the semiconductor chip 30 (reinforcing chip) up to 150 μm which is three times as thick as the first or second semiconductor chip, the amount of warping of the first semiconductor chip 20a was reduced to approximately 20 μm, which was reduced to half or below of the value obtained for the case where the thickness of the semiconductor chip 30 (reinforcing chip) was 50 μm. As is clear from the above, the results of the analysis indicates that the amount of warping of the first semiconductor chip 20a may largely be reduced, by thickening the semiconductor chip 30 (reinforcing chip).

The analysis in the above was based on an assumption that there were no microbumps connecting the first semiconductor chip 20a and the substrate 12. In a practical structure of the semiconductor device, taking bonding performance of the microbumps connecting the first semiconductor chip 20a and the substrate 12 into consideration, a practically sufficient level of rigidity may be ensured if the thickness of the semiconductor chip 30 (reinforcing chip) is twice or more, and preferably three times or more as large as the thickness of the first or second semiconductor chip.

It is apparent that the present invention is not limited to the above embodiment, that may be modified and changed without departing from the scope and spirit of the invention.

What is claimed is:

1. A semiconductor device comprising:
a substrate;
a stack placed on said substrate, and composed of a plurality of semiconductor chips, each having through electrodes, stacked while placing bumps connected to said through electrodes in between; and
a reinforcing chip provided on said stack specifically on the surface thereof opposite to the substrate-side surface, or between said substrate and said stack,
wherein thickness of said reinforcing chip is larger than the thickest semiconductor chip out of said plurality of semiconductor chips.

2. The semiconductor device as claimed in claim 1, wherein the thickness of said reinforcing chip is twice or more as large as the thickest semiconductor chip out of said plurality of semiconductor chips.

3. The semiconductor device as claimed in claim 1,
wherein flexural strength of said reinforcing chip is eight times or more as large as that of the thickest semiconductor chip out of said plurality of semiconductor chips.

4. The semiconductor device as claimed in claim 1,
wherein said reinforcing chip is provided to said stack specifically on the surface thereof opposite to said substrate-side surface.

5. The semiconductor device as claimed in claim 1,
wherein said bumps are microbumps.

6. The semiconductor device as claimed in claim 1,
wherein said substrate is an interposer.

7. The semiconductor device as claimed in claim 6,
further comprising a semiconductor chip provided on said substrate specifically on the surface thereof opposite to the surface on which said stack is provided.

8. The semiconductor device as claimed in claim 1,
wherein said reinforcing chip is a semiconductor chip.

9. The semiconductor device as claimed in claim 1,
wherein said reinforcing chip is a dummy chip composed of a material having a coefficient of thermal expansion nearly equal to that of said plurality of semiconductor chips.

10. The semiconductor device as claimed in claim 9,
wherein said dummy chip has a passive element.

11. The semiconductor device as claimed in claim 1,
wherein a gap between the adjacent ones of said plurality of semiconductor chips, and a gap between said stack and said reinforcing chip are filled with an underfill material.

12. The semiconductor device as claimed in claim 11,
wherein said underfill material contains an epoxy resin.

13. A method of fabricating a semiconductor device comprising:
heating a substrate up to a first temperature;
forming a stack on said substrate, by sequentially stacking a plurality of semiconductor chips, each having through electrodes, heated at a second temperature higher than said first temperature;
stacking, on said stack, a reinforcing chip thicker than the thickest semiconductor chip out of said plurality of semiconductor chips, heated up to said second temperature; and
cooling said substrate, said stack, and said reinforcing chip down to normal temperature.

14. The method of fabricating a semiconductor device as claimed in claim 13,
wherein said substrate has, on the surface thereof on which said semiconductor chip is mounted, an insulating layer and thereon an interconnect layer, and
after said cooling,
removing said substrate so as to expose said insulating layer, to thereby form an interposer.

15. The method of manufacturing a semiconductor device as claimed in claim 14, further comprising, after said forming said interposer:
heating said interposer, said stack, and said reinforcing chip up to said first temperature;
further bonding a semiconductor chip, heated up to said second temperature, to said interposer specifically on the surface thereof opposite to the surface on which said stack is mounted, while placing the bumps in between; and
cooling said interposer, said stack, said reinforcing chip, and said semiconductor chip provided to said interposer specifically on the surface thereof opposite to the surface having said stack mounted thereon, down to normal temperature.
